(19) United States
(12) Patent Application Publication
(10) Pub. No.: US 2025/0117987 A1
(43) Pub. Date: Apr. 10, 2025

(54) MAGNETIC RESONANCE IMAGING APPARATUS AND IMAGE PROCESSING METHOD

(71) Applicant: FUJIFILM Corporation, Tokyo (JP)

(72) Inventors: Toru SHIRAI, Tokyo (JP); Tomoki AMEMIYA, Tokyo (JP); Suguru YOKOSAWA, Tokyo (JP); Yukio KANEKO, Tokyo (JP); Atsuro SUZUKI, Tokyo (JP); Keisuke NISHIO, Tokyo (JP); Takenori MURASE, Tokyo (JP)

(73) Assignee: FUJIFILM Corporation, Tokyo (JP)

(21) Appl. No.: 18/907,178

(22) Filed: Oct. 4, 2024

(30) Foreign Application Priority Data
Oct. 6, 2023 (JP) 2023-174417

(51) Int. Cl. G06T 11/00; G01R 33/56; G01R 33/565

(52) U.S. Cl. CPC G06T 11/006; G01R 33/5608; G01R 33/56545; G06T 2210/41; G06T 2211/441

(57) ABSTRACT

Provided is a technology capable of reducing a load during a training process and an application process of a CNN, and performing effective ringing correction in accordance with a sampling pattern.

An aspect of the present invention provides an MRI apparatus including, as a ringing correction unit, a CNN for each sampling pattern. The CNN is trained by using a correct answer image in which rectangular or rectangular parallelepiped ringing in has not occurred and a plurality of processed pattern images. In the application of the CNN, measurement data is reconstructed at a desired reconstruction matrix size by performing zero-filling on the measurement data, and then a CNN corresponding to the sampling pattern of the measurement data is selected and applied to perform the ringing correction in a real space.

### CROSS-REFERENCE TO RELATED APPLICATIONS

The present application claims priority under 35 U.S.C. § 119 to Japanese Patent Application No. 2023-174417, filed Oct. 6, 2023. Each of the above application(s) is hereby expressly incorporated by reference, in its entirety, into the present application.

### BACKGROUND OF THE INVENTION

### 1. Field of the Invention

The present invention relates to a magnetic resonance imaging apparatus, and more particularly, to a ringing correction technology of an image acquired by the magnetic resonance imaging apparatus.

### 2. Description of the Related Art

In magnetic resonance imaging (MRI), a nuclear magnetic resonance signal (echo signal) applied with encoding in two-axial directions in a case of two-dimensional measurement or encoding in three-axial directions in a case of three-dimensional measurement is generated to acquire measurement data that is two-dimensional or three-dimensional k-space data. The MRI apparatus reconstructs an image of the subject by performing processing such as a Fourier transform on the measurement data.

A matrix size (measurement matrix size) and a data pattern for filling the k-space (sampling pattern) during measurement are determined by a pulse sequence used for imaging, but vary depending on imaging conditions such as restrictions of the apparatus and an imaging time.

On the other hand, in the reconstruction, the measurement data in a frequency domain is transformed into image data in a real space domain by performing an inverse Fourier transform, so the measurement data is processed as rectangular or rectangular parallelepiped data in terms of the operation of the inverse Fourier transform. In addition, the matrix size of the image to be reconstructed (reconstruction matrix size) may be the same as the measurement matrix size, but in order to obtain an image with a desired resolution, the image is often reconstructed with a matrix size different from the measurement matrix size.

Since the measurement matrix size is discrete and finite in a frequency space, in a case in which the measurement matrix size and the reconstruction matrix size are different from each other and a ratio thereof deviates from 1:1, a periodic or streak artifact called a Gibbs ringing or a truncation artifact (hereinafter referred to as ringing) is more strongly generated in the reconstructed image. This ringing can be suppressed, for example, by applying a k-space filter that smooths a high-frequency region to the measurement data, but it is necessary to adjust the k-space filter for each matrix size, and there is a disadvantage that the sharpness of the image is decreased and the image is blurred by the application of the k-space filter.

Meanwhile, various technologies have been proposed for obtaining an image with a reduced noise or artifact included in an image obtained by MRI by using a neural network. For example, Qianqian Zhang et al. Magn Reson Med. 2019; 82:2133-2145 proposes using a deep learning model, such as a CNN, which has been trained by using images reconstructed by combining various measurement matrix sizes and reconstruction matrix sizes. In addition, JP2019-202064A discloses a technology of extrapolating measurement data with signal defects using a CNN, and describes that activation parameters of the CNN are turned ON and OFF in accordance with imaging conditions, to handle to different sampling patterns (JP2019-202064A).

### SUMMARY OF THE INVENTION

The technology described in JP2019-202064A is a technology of, specifically, performing ON-OFF control of the activation parameters in accordance with the pulse sequences such as EPI, FSE, and FE, and ON-OFF control of the activation parameters taking into account the phase encoding direction and the k-space filling method (sampling pattern: Cartesian or radial), but does not address the correction of the ringing caused by a difference between the measurement matrix size and the reconstruction matrix size. In addition, the technology described in Qianqian Zhang et al. Magn Reson Med. 2019; 82:2133-2145 is based on the premise that the rectangular or rectangular parallelepiped sampling pattern, and an enormous amount of training data is required for training the CNN in order to handle a sampling pattern different from the rectangular or rectangular parallelepiped sampling pattern, so that it is difficult to construct the CNN, and the operation load is high during the application of the CNN.

An object of the present invention is to provide a technology capable of reducing a load during a training process and an application process of a CNN, and performing effective ringing correction in accordance with a sampling pattern.

In order to achieve the above-described object, an MRI apparatus of an aspect of the present invention comprises, as a ringing correction unit, a CNN for each sampling pattern. The CNN is trained by using a correct answer image in which rectangular or rectangular parallelepiped ringing in has not occurred and a plurality of processed pattern images.

That is, an aspect of the present invention provides an MRI apparatus comprising: an imaging unit that collects measurement data consisting of nuclear magnetic resonance signals; an image generation unit that has a function of reconstructing the measurement data at a desired reconstruction matrix size; and a ringing correction unit that corrects ringing that occurs in a reconstructed image in a case in which a measurement matrix size of the measurement data and the reconstruction matrix size are different from each other. The ringing correction unit includes a plurality of CNNs that have been trained by using, as training data, a correct answer image in which ringing has not occurred and an input image in which ringing has occurred, to correct the ringing of the input image. The plurality of CNNs each have different sampling patterns of the k-space data of the input image. The ringing correction unit includes a CNN selection unit that selects any one of the plurality of CNNs in accordance with a sampling pattern of the measurement data, and applies the selected CNN.

Another aspect of the present invention provides an image processing method of, in a case in which measurement data collected by an MRI apparatus is reconstructed at a reconstruction matrix size different from a matrix size of the measurement data, performing ringing correction by using a CNN that has been trained by using, as training data, a correct answer image in which ringing has not occurred and an input image in which ringing has occurred, to correct the ringing of the input image, in which the CNN includes a plurality of CNN that have been trained by using, as the input image, image data generated from a plurality of k-space data having different sampling patterns, and the image processing method comprises: selecting a CNN corresponding to a sampling pattern of the measurement data from among the plurality of CNNs and performing the ringing correction on the measurement data in a real space.

The image processing method according to the aspect of the present invention may be implemented by a computer within the MRI apparatus or by an image processing apparatus separate from the MRI apparatus.

According to the aspect of the present invention, since the CNN is prepared for each sampling pattern, a high ringing correction effect corresponding to the sampling pattern can be obtained. Since each CNN need only be trained by specializing in one sampling pattern, the training and application processes can be simplified. In particular, it is possible to create the training data corresponding to various sampling patterns by cutting out a predetermined sampling pattern from the k-space data of the correct answer image to form the k-space data as an image, and thus it is not necessary to capture and collect an enormous amount of data as the training data of the CNN, and the CNN for each sampling pattern can be extremely easily prepared.

### BRIEF DESCRIPTION OF THE DRAWINGS

FIG. 1 is a diagram showing an overall configuration of an MRI apparatus to which the present invention is applied.

FIG. 2 is a functional block diagram of an image processing unit according to an embodiment.

FIG. 3 is a diagram showing a sampling pattern.

FIG. 4 is a diagram showing an example of a structure of a CNN used in the embodiment.

FIG. 5 is a diagram showing training data for the CNN.

FIG. 6 is a diagram showing a function of each CNN.

FIG. 7 is a diagram showing an outline of an image processing procedure.

FIG. 8 is a diagram showing a ringing correction procedure using the CNN.

FIG. 9 is a diagram showing an application example of a plurality of CNNs.

FIG. 10 is a diagram showing an application example of the plurality of CNNs to a cylindrical sampling pattern.

### DESCRIPTION OF THE PREFERRED EMBODIMENTS

Hereinafter, embodiments of an MRI apparatus and an image processing method according to an embodiment of the present invention will be described with reference to the accompanying drawings.

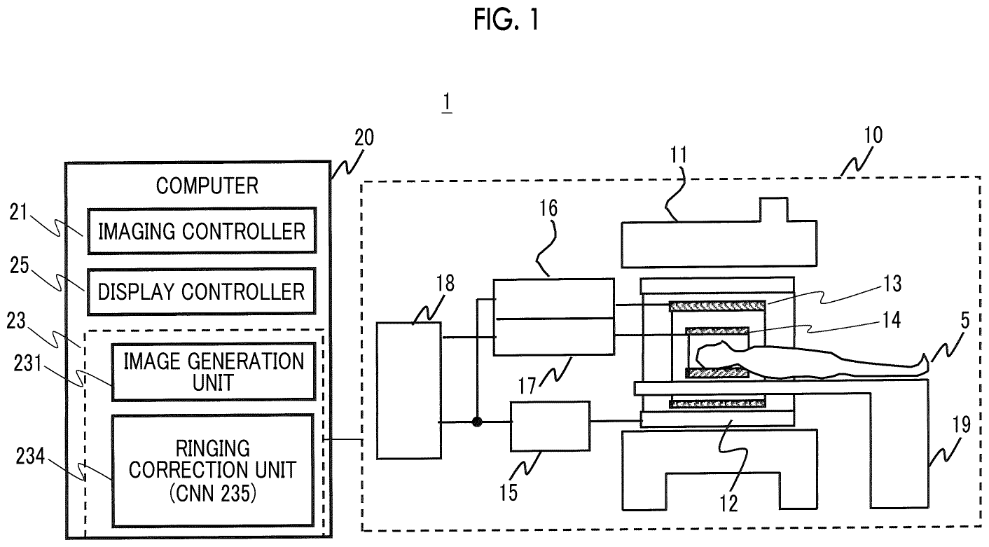

First, an outline of a configuration of an MRI apparatus 1 to which the present invention is applied will be described. The present invention can be applied to most types of MRI apparatuses that are currently in widespread use, and the configuration thereof roughly includes an imaging unit 10 that collects nuclear magnetic resonance signals, a computer 20 that controls the imaging unit and performs various types of operations, and various devices that are associated with the imaging unit 10 and the computer 20, such as an input device, a display device, and an external storage device, as shown in FIG. 1.

Since the configuration of the imaging unit 10 is the same as a configuration of a normal MRI apparatus, a detailed description thereof will be omitted, but the imaging unit 10 comprises a static magnetic field magnet 11 that generates a static magnetic field space in which a subject 5 is placed, a gradient magnetic field coil 12 that applies a gradient magnetic field in a static magnetic field, an RF transmission coil 13, an RF receive coil 14, a gradient magnetic field power supply 15 that drives these coils and a transmitter 16, a receiver 17 to which a high-frequency receive coil is connected, and a bed device 19 that transports the subject 5 into the static magnetic field space. Further, the imaging unit comprises a sequencer 18 that controls the operations of sampling the signals via the gradient magnetic field coil 12, the RF transmission coil 13, and the RF receive coil 14 in accordance with a pulse sequence.

The computer 20 includes an imaging controller 21 that controls the operation of the imaging unit 10 via the sequencer 18, an image processing unit 23 that performs image reconstruction and other processing on measurement data (k-space data) collected by the imaging unit 10, and a display controller 25 that controls the display of the reconstructed images, a GUI, and the like.

The computer 20 can be configured as a general-purpose computer comprising a CPU or a GPU and a memory, and the above-described functions of the computer are programmed in advance and realized by uploading the program to the CPU or the like. In addition, some functions of the computer may be realized by hardware such as an ASIC or a programmable IC, and the computer according to the embodiment of the present invention includes these hardware components.

### EMBODIMENT

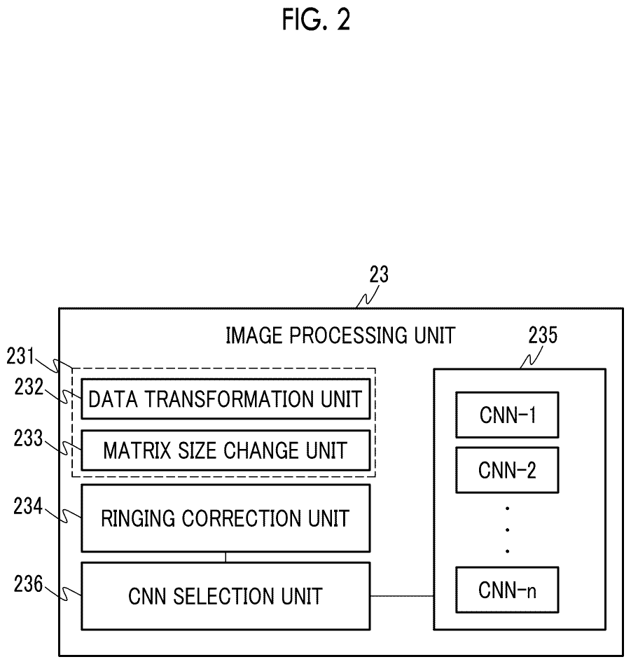

Hereinafter, an embodiment of the image processing unit 23 will be described. As shown in FIG. 2, the image processing unit 23 comprises an image generation unit 231 that performs operations such as a Fourier transform on the measurement data to generate an image having a desired reconstruction matrix size, and a ringing correction unit 234 that corrects the ringing that has occurred in the image.

The image generation unit 231 comprises a data transformation unit 232 that performs operations such as an inverse Fourier transform (IFT) or a Fourier transform (FT) to transform measurement space (frequency domain) data into real space data and to transform the real space data into the measurement space data, and a matrix size change unit 233 that performs processing such as data cutout and zero-filling on the measurement space data. The image generation unit 231 performs, on the measurement data collected by the imaging unit 10, image reconstruction at a reconstruction matrix size different from a measurement matrix size of the measurement data by using these functions.

The ringing correction unit 234 has a function of performing ringing correction on the reconstructed image generated by the image generation unit 231 and comprises a plurality of CNNs 235 (CNN-1, CNN-2, . . . , CNN-n) that have trained to obtain a ringing correction effect for each sampling pattern of the measurement data, and a CNN selection unit 236 that selects the CNN corresponding to the measurement data, which is the correction target, from among the plurality of CNNs 235.

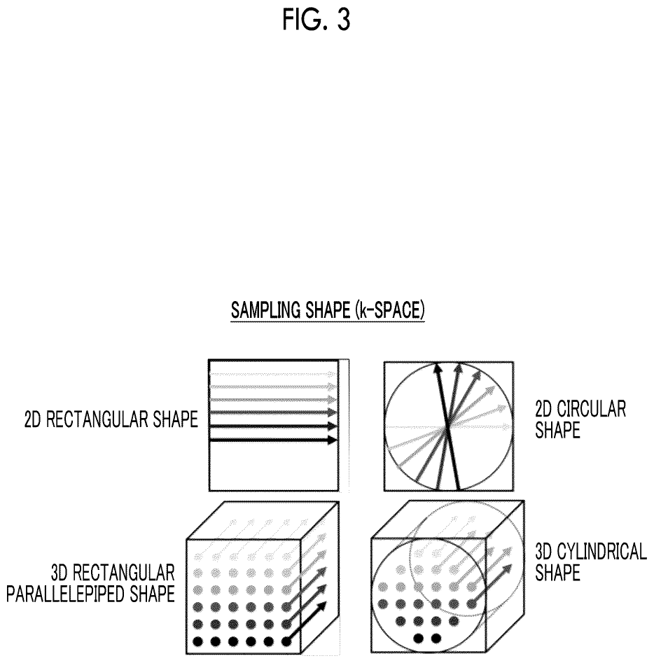

The sampling pattern of the measurement data is a disposition pattern of the measurement data in the k-space, and as shown in FIG. 3, in a case of two-dimensional data, a rectangular sampling pattern is obtained in raster scanning in which the k-space is sampled in parallel along one axis (for example, a kx axis), and an elliptical sampling pattern is obtained in radial scanning in which the k-space is sampled radially with an origin of the k-space as the center. In addition, in a case of the three-dimensional data, the sampling pattern is a rectangular parallelepiped sampling pattern in the former case and a cylindrical or spherical sampling pattern in the latter case. It should be noted that the cylindrical sampling pattern is a pattern obtained by continuously performing two-dimensional radial scanning in a direction orthogonal to an axial direction. The spherical pattern is a pattern obtained in a case in which the k-space is sampled radially in three dimensions with an origin of a three-dimensional k-space as the center.

Next, a CNN corresponding to each sampling pattern will be described. Hereinafter, in order to simplify the description, a CNN of the cylindrical sampling pattern is described as a representative of the cylindrical and spherical sampling patterns.

The CNN has, generally, a structure in which a plurality of convolution layers and pooling layers are stacked between an input layer and an output layer, and coefficients or weights of the layers are changed through training, so that a desired output is obtained. In the present embodiment, such a general CNN can also be adopted, but a complex-valued CNN is adopted because a complex image can be obtained in the MRI. By using the CNN corresponding to the complex image, the processing can be performed without being affected by an intensity or a phase of the signal.

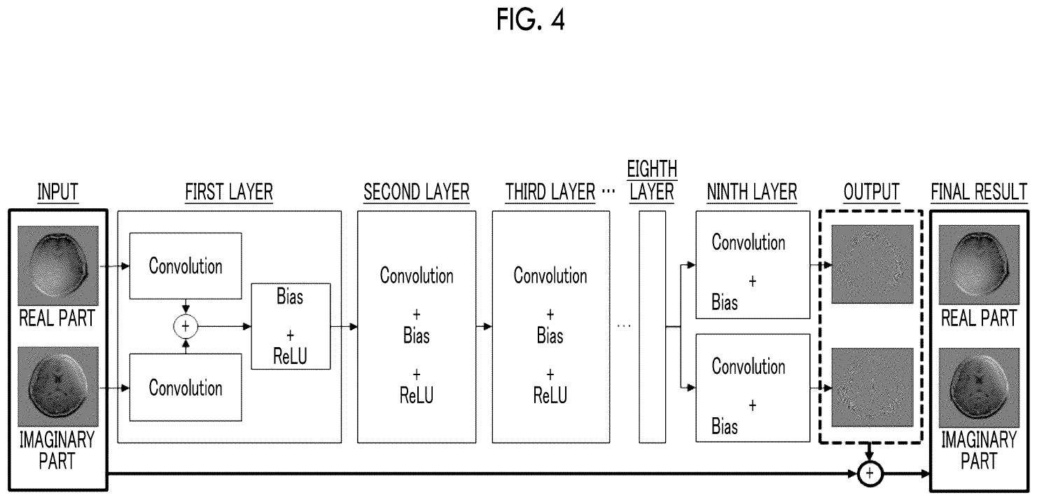

FIG. 4 shows an example of the complex-valued CNN adopted in the present embodiment.

The CNN 235 is a complex-valued CNN having a nine-layer structure in which each layer is formed by a block consisting of a convolution layer, an activation function (ReLU), and a pooling layer, the real part and the imaginary part of the input image are combined in the first layer, and the real part and the imaginary part are separated in the ninth layer. It should be noted that a kernel size or the number of channels of each layer is not particularly limited, but for example, the kernel size can be “3×3” to “9×9”, and the number of channels can be “16 ch” to “128 ch”. Although a simple CNN is shown as an example in the present embodiment, the CNN is not limited to this. For example, a resolution-changed CNN, such as U-net, may be used.

In the training of the CNN, the weights and the biases of the CNN are trained by using, as training data, an image (correct answer image) captured under conditions in which the ringing has not occurred or almost no ringing has occurred, and an image (input image) in which the ringing has occurred, such that an image close to the correct answer image is output with respect to the input image.

As the correct answer image, in a case of three-dimensional measurement data, an image reconstructed from the measurement data (three-dimensional k-space data) captured by the three-dimensional measurement with a large measurement matrix size is used. In a case in which the measurement matrix size is equal to or larger than the reconstruction matrix, almost no Gibbs ringing occurs in the reconstructed image.

The input image in which the ringing has occurred is an image obtained by cutting out the measurement data of a desired sampling pattern from a low-frequency region of the measurement data obtained by the above-described three-dimensional measurement, performing zero-filling of the high-frequency region outside the cutout measurement data to obtain the k-space data having the same size as the original measurement data, and performing reconstruction.

The same applies to the two-dimensional measurement data, an image reconstructed from the measurement data (two-dimensional k-space data) captured at a large measurement matrix size is set used as the correct answer image, and an image obtained by cutting out the low-frequency region of the measurement data and performing zero-filling of the high-frequency region to be transformed into the real space data is used as the input image.

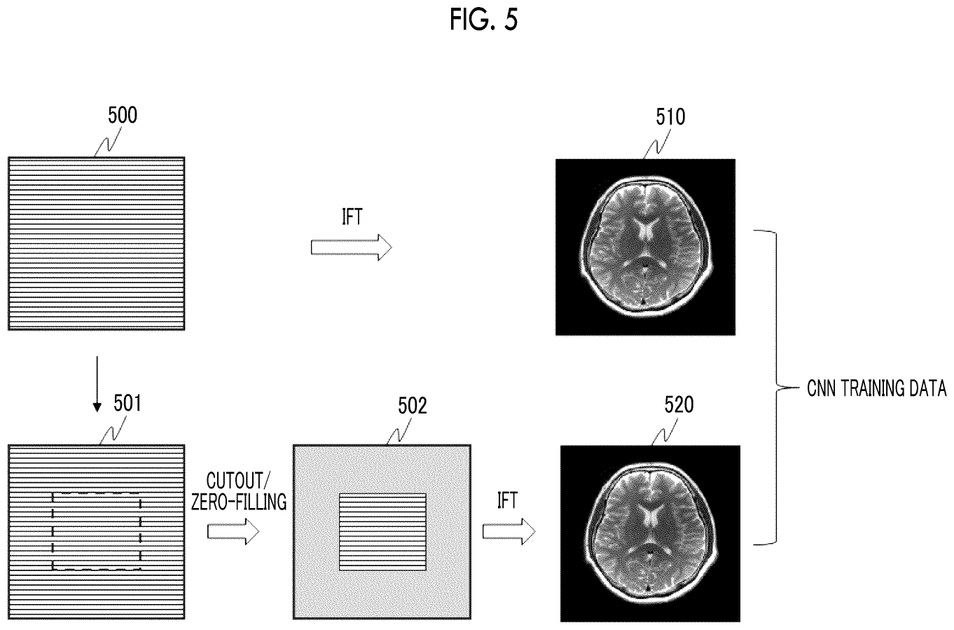

FIG. 5 shows a procedure for creating the input image for the rectangular sampling pattern from the correct answer image as an example. As shown in FIG. 5, an input image 520 is obtained by cutting out a low-frequency region (region surrounded by a dotted line) 501 from measurement data 500 obtained by being captured for a correct answer image 510, performing zero-filling of the outside of the cutout measurement data to obtain measurement data 502 having the same size as the measurement data 500, and performing an inverse Fourier transform (IFT) on the measurement data 502. By changing the shape of the low-frequency region 501 shown in FIG. 5 from a rectangular shape to an elliptical shape, an input image for an elliptical sampling pattern is obtained.

The same applies to the measurement data (three-dimensional k-space data) obtained by the three-dimensional measurement, data of a low-frequency region, including the center of the three-dimensional k-space data, is cut out with a predetermined sampling pattern (cylindrical or spherical), the high-frequency region around the cutout data is expanded by zero-filling, and the data is subjected to an inverse Fourier transform to obtain a three-dimensional input image.

It should be noted that, in a case of three-dimensional measurement data, the cutout of the low-frequency region from the original measurement data, that is, the deletion of the high-frequency region, may be performed in each three-dimensional direction or may be performed only in the two-dimensional or one-dimensional direction. For the two-dimensional measurement data, the deletion of the high-frequency region may be performed in each two-dimensional direction or may be performed only in the one-dimensional direction. Since the CNN having a ringing correction effect for such a low-dimensional direction can be trained by using the training data having a small number of dimensions, it is possible to easily create the training data and construct the CNN with less burden. Application of the CNN using the input image obtained by performing the cutout and zero-filling in the low-dimensional direction will be described in detail in the following embodiment of the application.

In addition, for a ratio (hereinafter referred to as a matrix ratio) between the size (size in each axial direction) of the cutout k-space data and the matrix size (size in each axial direction) of the k-space data after expansion, a plurality of input images having different matrix ratios may be used for training one CNN, or a CNN can be prepared for each matrix ratio by using the input image having a typical matrix ratio (reconstruction matrix size/measurement matrix size) such as 1.5 times or 2 times. In this case, the number of CNNs is “the number of sampling patterns (the sum of the number of two-dimension and three-dimension)” x “the number of different matrix ratios”.

By preparing a large number of such combinations of the correct answer image 510 and the input image 520 and performing training using the combinations of the correct answer image 510 and the input image 520 as the training data, the trained CNN can output an image close to the correct answer image, that is, the ringing-corrected image, with respect to the input image. In addition, in a case in which the image after the ringing correction is subjected to a Fourier transform to be restored to the data in the measurement space, the data in the high-frequency region is extrapolated, and the step generated between the low-frequency region and the high-frequency region is eliminated by zero-filling. That is, the measurement data has the main cause of the Gibbs ringing removed.

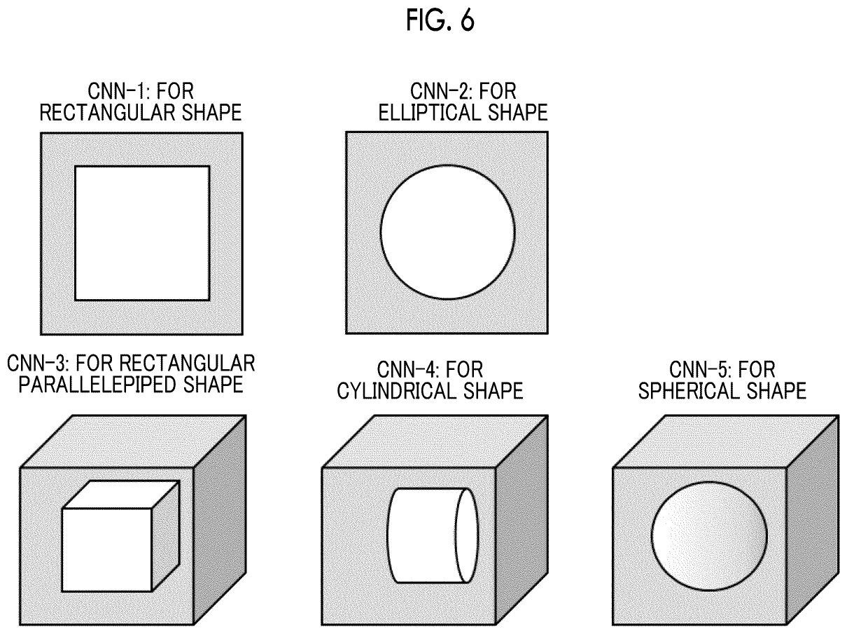

FIG. 6 shows a main example of the CNN obtained in the present embodiment. Here, since the function of the CNN is extrapolation in the measurement space, the CNN is represented using this function. In FIG. 6, a CNN-1 is a CNN for a rectangular shape having a function of extrapolating the high-frequency region with respect to the measurement data of the rectangular sampling pattern, a CNN-2 is a CNN for an elliptical shape having a function of extrapolating the high-frequency region with respect to the measurement data of the elliptical sampling pattern, a CNN-3 is a CNN for a rectangular parallelepiped shape having a function of extrapolating the high-frequency region with respect to the measurement data of the rectangular parallelepiped sampling pattern, a CNN-4 is a CNN for a cylindrical shape having a function of extrapolating the high-frequency region with respect to the measurement data of the cylindrical sampling pattern, and a CNN-5 is a CNN for a spherical shape having a function of extrapolating the high-frequency region with respect to the measurement data of the spherical sampling pattern.

It should be noted that, although the CNNs corresponding to the sampling patterns of the two-dimensional and three-dimensional data are shown in FIG. 6, it is also possible to perform higher dimension ringing correction by applying the CNNs, which have been trained to obtain a ringing correction effect for the one-dimensional direction or the two-dimensional direction, in combination, and it is not always necessary to comprise all five types of CNNs shown in FIG. 6.

As described above, in the present embodiment, during the training of the CNN, it is possible to generate input images of various sampling patterns by simply performing high-resolution imaging of one correct answer image for one set, and thus it is possible to construct a plurality of CNNs corresponding to the sampling patterns with less burden.

It should be noted that the ringing correction unit 234 may comprise a filter or the like generally used in the ringing correction, in addition to the plurality of CNNs having different sampling patterns described above. It is also possible to improve the accuracy of the ringing correction by using, in the application process of the CNN, the filter in a supplementary manner in a case in which the matrix ratio of the measurement matrix size of the image that is the ringing correction target is different from the matrix ratio of the input image used for training the CNN.

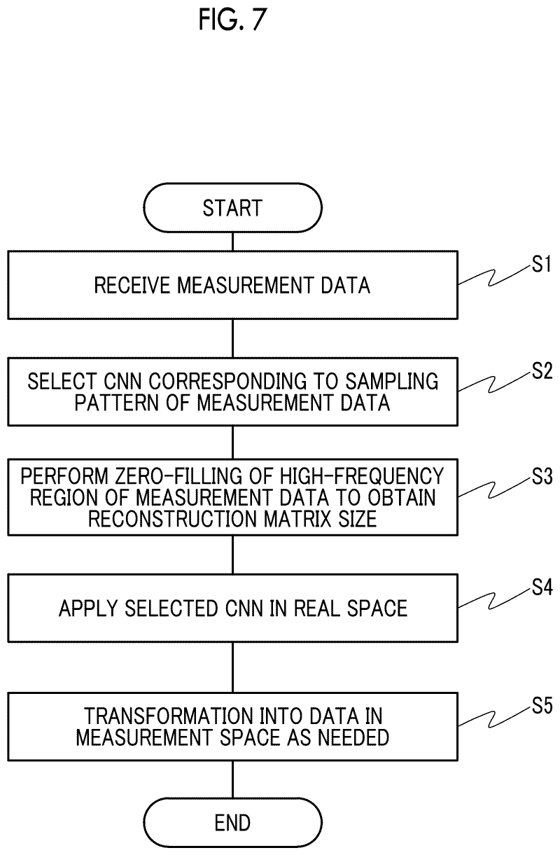

Next, a flow of processing in the image processing unit 23 having the above-described configuration will be described. FIG. 7 shows the flow of the processing.

First, in a case in which the image processing unit 23 receives the measurement data from the imaging unit 10 (S1), the CNN selection unit 236 determines the sampling pattern by referring to the pulse sequence executed by the imaging unit 10 to collect the measurement data or the measurement data itself, and selects the CNN to be used for the ringing correction from among the plurality of CNNs 235 based on this determination (S2). For example, in a case in which the measurement data is two-dimensional data, such as kx-ky space data for each slice, and the raster scanning is performed, the CNN-1 (FIG. 6) for the rectangular sampling pattern is selected, and in a case in which the measurement data is two-dimensional data and the radial scanning is performed, the CNN-2 for the elliptical sampling pattern is selected. In a case in which a plurality of CNNs are applied in combination, a plurality of CNNs are selected.

In addition, in a case in which the ringing correction unit 234 comprises a CNN for each sampling pattern corresponding to each matrix ratio, the CNN, which has been trained by using the training data having the matrix ratio that is the same as or closest to the ratio between the measurement matrix size of the target measurement data and the reconstruction matrix size, is selected.

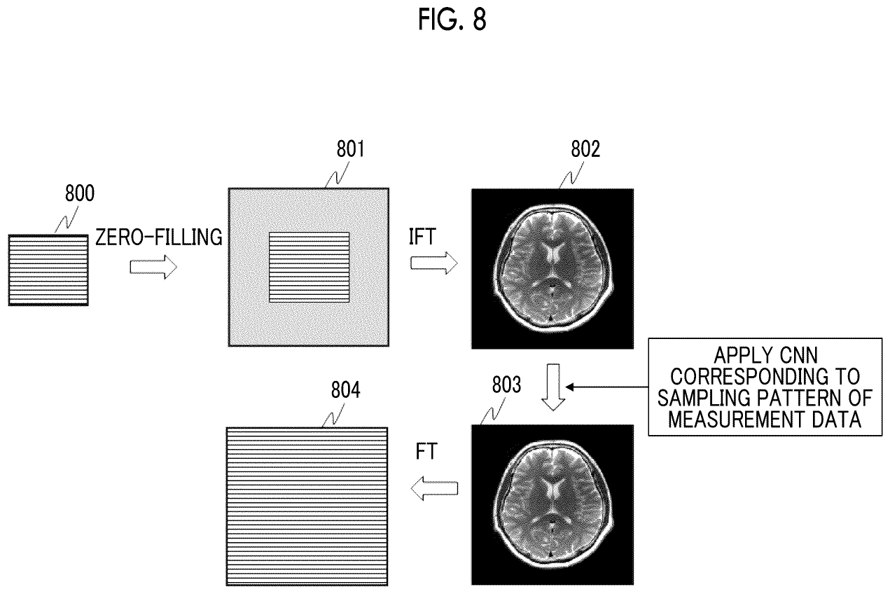

Next, the measurement data is subjected to an inverse Fourier transform to have the desired reconstruction matrix size (S3). For example, in a case in which the measurement data is rectangular two-dimensional data, as shown in FIG. 8, the periphery of measurement data 800 is expanded by zero-filling to obtain rectangular k-space data 801 having the same size as the reconstruction matrix size, and then the rectangular k-space data 801 is subjected to an inverse Fourier transform to obtain an input image 802 for the CNN. The CNN selected in S2, for example, the CNN-1, is applied to the input image 802 to obtain an output image 803 in which the ringing that has occurred in the image is corrected (S4).

The output image 803 may be used as the final reconstructed image obtained from the input measurement data to complete the processing, but the output image 803 may be subjected to a Fourier transform again to obtain measurement data 804 in which the high-frequency region is extrapolated (S5), and then further processing in the measurement space, such as filtering or noise removal, may be performed.

With the MRI apparatus according to the present embodiment, the MRI apparatus comprises the ringing correction unit comprising the plurality of CNNs trained to obtain a ringing correction effect for each sampling pattern, and one or a plurality of CNNs are selected from the plurality of CNNs and applied in accordance with the sampling pattern of the measurement data that is the processing target, so that an effective ringing correction effect can be obtained for each sampling pattern. In addition, since each CNN can be trained by using the image created using the measurement data of the correct answer image, it is possible to reduce the effort and time required for capturing an enormous amount of training data.

Hereinafter, a specific example of the selection of the CNN and the application of the CNN for each sampling pattern will be described.

### Example 1

This example, is an example in which, as shown in FIG. 6, the ringing correction unit 234 comprises five types of CNNs corresponding to the two-dimensional and three-dimensional sampling patterns, and in this case, the dimension and the sampling pattern of the measurement data and the dimension and the sampling pattern of the CNNs correspond to each other one-to-one, and the corresponding CNN is selected and applied in the application of the CNN (FIG. 8).

### Example 2

This example shows a case in which a CNN trained to obtain a ringing correction effect for the one-dimensional direction is provided. The CNN trained in the one-dimensional direction uses, for the input image for training the CNN, data obtained by performing zero-filling of the high-frequency region in the one-dimensional direction on the data cut out from the correct answer image, to expand the data. By performing the cutout on both the rectangular and circular sampling patterns, the CNN for the one-dimensional direction correction for each sampling pattern can be obtained.

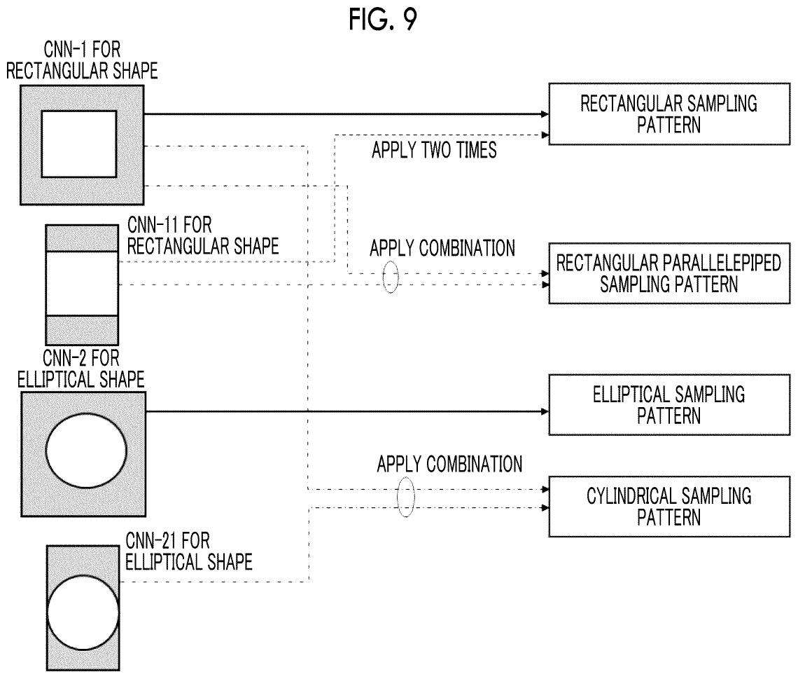

This is applied in multiple stages in combination with the CNN for other sampling patterns to perform the ringing correction on the two-dimensional or three-dimensional measurement data or the reconstructed image thereof. An example of the combination method is shown in FIG. 9. In FIG. 9, a solid line shows processing of Example 1, and a one-dot chain line shows processing of the present example.

As shown in FIG. 9, in Example 1, the CNN-3 of FIG. 6 is applied to the three-dimensional measurement data of the rectangular parallelepiped sampling pattern, but in the present example, the CNN-1 for the rectangular shape is applied, and then a CNN-11 for one-dimensional direction correction is applied to perform the ringing correction on the real space of the rectangular parallelepiped measurement data. The order in which the CNN-1 and CNN-11 are applied may be reversed.

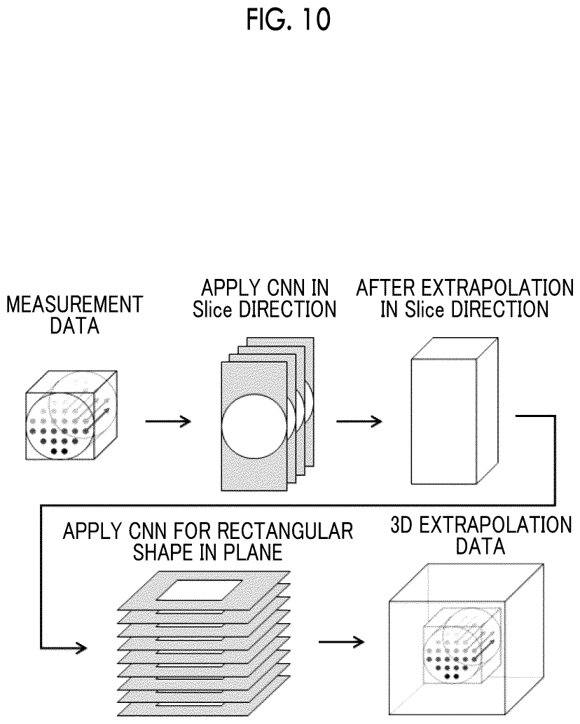

For the three-dimensional measurement data of the cylindrical sampling pattern, for example, as shown in FIG. 10, a CNN-21 for a one-dimensional direction correction of an elliptical shape is sequentially applied along one axis (for example, the phase encoding direction or the frequency encoding direction), the high-frequency region is extrapolated in a slice axial direction, and then the CNN-1 for the rectangular shape is sequentially applied along the slice direction to the plane orthogonal to the slice direction to perform the extrapolation in the plane, thereby finally obtaining the measurement data extrapolated in the three-dimensional direction.

In the present example, since the CNN-3 for the three-dimensional correction can be omitted, the CNN can be trained and applied with a lower load.

### Example 3

In Example 2, different types of CNNs are combined, but in the present example, the same CNN is used in multiple stages. For example, the CNN-11 for the one-dimensional direction correction is applied to the measurement data of the rectangular sampling pattern for one dimension, and then applied for the other dimension. In this case, as the CNN-11 for the one-dimensional direction correction, two types for the ky direction and the kx direction may be provided, but the image to which the CNN for the one direction correction is to be applied is transposed, the direction of the ringing correction and the direction of the correction learned by the CNN are matched each other, and then the CNN is applied. In a case of a three-dimensional rectangular parallelepiped sampling pattern, the ringing correction can be similarly performed by repeating the application of the CNN.

Although the example of the application of the CNN is described with reference to FIG. 9, the combination of the CNN shown in FIG. 9 and the multi-stage application are merely examples, and combinations other than those shown in FIG. 9 can also be used as long as the combination is finally adapted to the sampling pattern that is the correction target.

Although the embodiments of the MRI apparatus and the image processing with respect to the measurement data obtained by the MRI apparatus according to the embodiment of the present invention, particularly, the ringing correction, are described above, the present invention is characterized by preparing a plurality of CNNs that can perform the ringing correction with less burden and more effectively in correspondence with the sampling pattern of the measurement data and selecting and applying the CNNs, and the present invention is not limited to the contents described as the embodiment and the examples.

The image processing method according to the embodiment of the present invention is not limited to being executed in the MRI apparatus, and is also applied to a case of being executed in an image processing apparatus independent of the MRI apparatus.

### EXPLANATION OF REFERENCES

10: imaging unit
20: computer
23: image processing unit
231: image generation unit
232: data transformation unit
233: matrix size change unit
234: ringing correction unit
235: CNN
236: CNN selection unit

What is claimed is:

1. A magnetic resonance imaging apparatus comprising:
an imaging unit that collects measurement data consisting of nuclear magnetic resonance signals;
one or more processors that have a function of reconstructing the measurement data at a desired reconstruction matrix size, and correcting ringing that occurs in a reconstructed image in a case in which a measurement matrix size of the measurement data and the reconstruction matrix size are different from each other,
wherein the r one or more processors include
a plurality of CNNs that have been trained by using, as training data, a correct answer image in which ringing has not occurred and an input image in which ringing has occurred, to correct the ringing of the input image and that have different sampling patterns of k-space data of the input image, and select any one of the plurality of CNNs in accordance with a sampling pattern of the measurement data and apply the selected CNN.

2. The magnetic resonance imaging apparatus according to claim 1,
wherein the CNNs have been trained by using, as the input image, an image obtained by cutting out a low-frequency region with a predetermined sampling pattern from k-space data of the correct answer image, performing zero-filling of a high-frequency region, and performing transformation into image data.

3. The magnetic resonance imaging apparatus according to claim 1,
wherein the one or more processors include, as the plurality of CNNs, a CNN that has been trained to perform ringing correction on measurement data having a rectangular sampling pattern and a CNN that has been trained to perform ringing correction on measurement data having an elliptical sampling pattern.

4. The magnetic resonance imaging apparatus according to claim 3,
wherein the CNN that has been trained to perform the ringing correction on the measurement data having the rectangular sampling pattern and the CNN that has been trained to perform the ringing correction on the measurement data having the elliptical sampling pattern each include a CNN that has been trained to correct ringing in a one-dimensional direction and a CNN that has been trained to correct ringing in a two-dimensional direction.

5. The magnetic resonance imaging apparatus according to claim 1,
wherein, in a case in which the measurement data is three-dimensional data obtained by radial scanning, the one or more processors select a combination of a CNN for a cylindrical or spherical sampling pattern or a CNN for an elliptical sampling pattern and a CNN for a rectangular sampling pattern.

6. The magnetic resonance imaging apparatus according to claim 1,
wherein, in a case in which the measurement data is three-dimensional data obtained by raster scanning, the one or more processors select a CNN for a rectangular parallelepiped sampling pattern or a CNN for a rectangular sampling pattern.

7. An image processing method of, in a case in which measurement data collected by a magnetic resonance imaging apparatus is reconstructed at a reconstruction matrix size different from a matrix size of the measurement data, performing ringing correction by using a CNN that has been trained by using, as training data, a correct answer image in which ringing has not occurred and an input image in which ringing has occurred, to correct the ringing of the input image,
wherein the CNN includes a plurality of CNN that have been trained by using, as the input image, image data generated from a plurality of k-space data having different sampling patterns, and
the image processing method comprises:
selecting a CNN corresponding to a sampling pattern of the measurement data from among the plurality of CNNs and performing the ringing correction on the measurement data in a real space.

8. The image processing method according to claim 7,
wherein each of the plurality of CNNs has been trained by using, as the input image data, image data obtained by cutting out a low-frequency region with a predetermined sampling pattern from k-space data of the correct answer image, performing zero-filling of a high-frequency region, and then performing transformation into real space data.
